(19) United States
(12) Patent Application Publication
(10) Pub. No.: US 2008/0283943 A1
(43) Pub. Date: Nov. 20, 2008

(54) Electronic Device Comprising a Mems Element

(75) Inventors: Ronald Dekker, Eindhoven (NL); Hauke Polhmann, Hamburg (DE); Martin Duemling, Hamburg (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/093,996

(22) PCT Filed: Nov. 7, 2006
(86) PCT No.: PCT/IB2006/054142

§ 371 Date: May 16, 2008

(30) Foreign Application Priority Data
Nov. 17, 2005 (EP) 05077619.4

(51) Int. Cl. H01L 21/50; H01L 29/84

(52) U.S. Cl. 257/415; 438/52; 257/E29.324; 257/E21.499

(57) ABSTRACT

The device (100) comprises a MEMS element (60) in a cavity (30) that is closed by a packaging portion (17) on a second side (2) of the substrate (10). Contact pads (25) are defined on a flexible resin layer (13) on an opposite first side (1) of the substrate. Electrical connections (32) extend through the resin layer (13) to at least one element of the device (100). The device (100) is suitably made with the use of a temporary carrier (42), and opening of etching holes (18) from the second side (2) of the substrate (10).

The invention relates to a method of manufacturing an electronic device that comprises a microelectromechanical (MEMS) element which is provided with a fixed electrode and a movable electrode, which is defined in a cavity and is movable towards and from the fixed electrode between a first gapped position and a second position, said method comprising the steps of:

providing a substrate with a first and an opposite second side and with a sacrificial portion;

providing contact pads on the first side of the substrate, to which contact pads the electrodes of the MEMS element are electrically coupled;

providing a temporary carrier on the contact pads; providing at least one etching hole in the substrate from the second side, which etching hole extends to the sacrificial portion of the substrate;

removing the sacrificial portion through the at least one etching hole in the substrate, therewith forming the cavity;

closing the at least one etching hole on the second side of the substrate; and

removing the temporary carrier.

The invention also relates to an electronic device comprising a substrate of a semiconductor material with a first and an opposite second side and a microelectromechanical (MEMS) element which is provided with a fixed and a movable electrode, which is defined in a cavity and is movable towards and from the fixed electrode between a first gapped position and a second position, which cavity is opened through holes in the substrate that are exposed on the second side of the substrate, said electrodes being electrically coupled to contact pads that are present on the first side on the substrate.

Such a method and such a device are known from WO-A 2004/71943. The known method relates to the manufacture of a microelectromechanical system (MEMS) element as the electrical element. Such an element comprises a fixed electrode and a movable electrode. The movable electrode is defined in a cavity and is separated by a gap in an opened position. The movable electrode can move towards and away from the fixed electrode. In a sensor, the movement occurs due to external forces. In a capacitor or a switch, movement occurs due to application of an actuation voltage. The MEMS element in the known device is in particular a sensor. A circuit of semiconductor elements is present at the first side of the substrate. This circuit is specifically adapted to read out the signal generated in the MEMS element. Contact pads are defined and electrically connected to the circuit.

In the known method, use is made of a substrate with a buried insulating layer, that functions as the sacrificial portion. The movable and the fixed electrode are defined in the bottom semiconductor layer and extend perpendicular to the substrate plane. The at least one etching hole is in fact a pattern of channels between the said electrodes, and these holes are provided with reactive ion etching. The cavity in which the movable electrode is present, is formed by both the channels and the sacrificial portion.

Prior to definition of the channels electrically conducting contact plugs have been defined in the buried insulating layer from the first side of the substrate. The removal step of the insulating portion is then carried out as an underetching process. This is controlled so as to release the movable electrode without dividing the substrate into two separate portions. The closing of the etching holes is then achieved by the provision of a capping layer on the second side, which is a body of a semiconductor or polymer material or a glass plate. The capping layer closes the cavity and provides stability. In order to prevent adhesion of the capping layer to the movable electrode, this movable electrode has been thinned slightly prior to the provision of the etching holes.

It is a disadvantage of the known method that the provision of the capping layer requires the slight thinning of the movable electrode. This thinning is carried out by etching, for which an additional mask step is required. If there is some misalignment yield will reduce tremendously. Moreover, a mask is usually applied to the second side of the substrate. The presence of the cavity, as a result of the local thinning, may give rise to problems in the definition of the etch mask.

It is therefore a first object of the invention to provide a method of the kind described in the opening paragraph with an improved packaging of the cavity.

It is a second object to provide a device of the kind mentioned in the opening paragraph that is obtainable with the method of the invention.

These objects are achieved in that a resin layer is provided between the electrodes of the MEMS element and the contact pads, through which resin layer electrical connections extend to at least one element of the device, and that the substrate is provided with a packaging portion on the second side of the substrate through which the etching holes extend, while the sacrificial portion is at least partially present between the movable electrode and the packaging portion

The problem of the invention is in fact solved with a modified structure of the MEMS element, and a correspondingly modified method. According to the invention, the movable electrode overlies part of the substrate, i.e. the packaging portion. The cavity thus is present between both of them. Whereas in the prior art, the one or more etching holes provided the spacing between the movable and the fixed electrode, the at least one etching hole in the device of the invention has mainly the purpose of giving access to the sacrificial portion. After removal of that sacrificial portion, it can thus be closed with a layer that in any manner bridges merely the etching hole.

As a consequence of this simple closing of the at least one etching hole there is no need to use a rigid body as the capping layer. However, this possible absence of a rigid body requires another solution for the stability of the device. This is achieved in the invention by providing a flexible resin layer, which acts as a handling carrier. The resin layer is present on the first side of the substrate. The contact pads are then provided on top of the resin layer, while vertical interconnects extend through the resin layer to the at least one element. This may be the MEMS element, but could also be another element, such as a detection circuit, a driver, or the like. A second resin layer may be applied on the second side of the substrate, after closing the at least one etching hole. This will further improve the stability.

One advantage of the present invention is that it allows flip-chip assembly of the device to an external board, such that the MEMS element is remote from this external board. This is advantageous for the performance, particularly for sensors and resonators, as the MEMS element will not or not substantially be disturbed by power lines and magnetic fields in or near to such an external board.

Another advantage of the present invention is that the resin layer will act as a stress release. This appears particularly relevant so as to release stresses during thermal cycling. It is observed that thermal cycling is a relevant problem for such MEMS devices, and particularly in embodiments wherein the MEMS is provided with an actuation electrode and means for providing an actuation voltage, e.g. a resonator, tunable capacitor, switch. The problem is that the needed actuation voltages are rather substantial, which evidently leads to heat dissipation.

In an advantageous embodiment, the substrate is patterned into islands. As is known, a flexible circuit has an inherent tendency to bend and roll up itself. The consequence of this bending is severe mechanical stress. Such stress leads to irreversible deformation, such as cracks. It thus also leads to a deformation of the MEMS element, e.g. the positioning of the movable electrode with respect to the fixed electrode. Such an uncontrollable deformation is undesired, as it may reduce lifetime of the device and bring the device out of specifications. Now, by effectively patterning the substrate into islands, the bending and the resulting stress need not to be the same everywhere in the device. Effectively, the bending will be limited in the areas corresponding to the substrate islands and more pronounced in the other areas.

The closing of the etching holes can be carried out with different means. The use of a rigid body is not excluded, but not preferred: either it must be separated and extends outside the substrate islands, or separate caps must be provided for each island with a MEMS element, e.g. not on wafer level. A better alternative constitutes the use of a prepatterned tape, such as available as a solder resist. A flexible metal foil is a further alternative. One example hereof is known from WO-A 2003/84861.

A further option constitutes the provision of a passivation layer. Such layers may be deposited with chemical vapour deposition and are then able to close trenches. The use of chemical vapour deposition for sealing a cavity by covering holes or slits in a membrane is known per se, for instance from Q. Zou et al., Sensors and Actuators A, 72 (1999), 115-124. However, this document discloses the sealing of the cavity at a first side of the substrate only. Moreover, the cavity is defined in that method by etching through the slits in the membrane. It is not clear how a MEMS element with a movable element can be defined within this cavity and it appears impossible to do that. Actually, the sealed membrane in this document appears to be the movable element in itself. This sealed membrane is not protected with a separate capping layer.

Advantageously, the device comprises more than one substrate island. One island is suitable used for the MEMS element, whereas another island is used for the further circuit elements. Suitably, the further circuit elements comprise active elements such as transistors. These circuit elements then may constitute a detection circuit. The use of a high-voltage process with DMOS transistors such as referred to in the prior art document appears advantageous. Alternatively or additionally, the further circuit elements may be passive components, such as capacitors, and particularly trench capacitors.

It is highly suitable that the elements in the first substrate island and a further substrate island are mutually coupled with conductors that may be deformed in a lateral direction without the generation of substantial stress. This is enabled, particularly, by a geometric substructuring, for instance in the form of reinforcing ribs having an arbitrary shape, or in the form of a spiral. Such conductors are suitably provided near to the resin layer or even in between of several resin layers. This is known per se from US-B 6,479,890.

It is furthermore suitable in the method to apply an underbump metallisation and suitably solder material on the contact pads before the attachment of the circuit to a temporary carrier. This is particularly achievable with contact pads that are present on the resin layer. Bumps may then be provided on wafer level, for instance with electroplating, electroless metallisation or with immersion solder bumping. Use can be made of fine-pitch bumps herein, since use is made of a resin as the handling carrier. This implies that the difference between the coefficient of thermal expansion of the device and of a polymer carrier such as a printed circuit board, on which the device is to be mounted, is small. The solder balls thus do not need to compensate for those differences, and may be reduced in height, size and pitch.

It is moreover advantageous that any separation lanes are provided in areas outside the substrate islands. This implies that one does not need to separate through the substrate, reducing the amount of stress introduced in the device. Suitably, the separation lanes have additionally been kept free of any ceramic material, such as silicon oxide and silicon nitride layers, on the first side of the substrate.

In order to reduce the etching time, it is suitable to reduce the thickness of the substrate before the definition of the etching holes. This substrate reduction can be carried out with a conventional technique such as grinding, etching or chemical-mechanical polishing. Suitably the thickness of the substrate is reduced to less than 50 microns, preferably in the range of 20-30 microns. The diameter of the etching holes is suitably in the order of 1-2 microns. In the context of this application, the term ‘etching holes’ is understood to cover holes in any kind of shape, circular, elongate, with the exception of ringshaped as the latter will lead to removal of a larger area of the substrate.

Suitably, at least part of the sacrificial portion of the substrate is defined on the first side thereof. Shallow trench isolation may be used as at least part of the sacrifical portion of the substrate. This is laterally surrounded by substrate posts, which at the same time allow a precise definition of the insulating portion and thus of the substrate portion to be removed. As the substrate posts are defined by processing from the first side of the substrate, they may be provided on a high resolution, e.g. on submicron scale. This allows that the posts are flexible and/or have a spring-like character. Additionally, no buried insulating layer is needed in the substrate with this embodiment, which allows the choice of a low-cost substrate. Then, suitably the movable electrode is defined in the polysilicon or metal layer applied directly on the first side of the substrate. It will be understood that both vertical and horizontal versions of MEMS element may be designed in this manner.

If the electrodes of the MEMS element are defined vertically, which is substantially perpendicular to the substrate plane, then the sacrificial layer is defined by modification of the semiconductor layer. Parts of this semiconductor layer could be modified in a chemical reaction or alternatively be removed and the resulting trenches filled with another material. Such other material is suitably an oxide or possibly a nitride but other materials including polymers with sufficient temperature stability such as benzocyclobutene (BCB) can be used alternatively.

If the electrodes are defined horizontally, e.g. substantially parallel to the substrate plane, one of the electrodes is provided in the top semiconductor layer while the other electrode may be defined in a metal layer or a polysilicon layer. A field oxide or shallow trench isolation of the substrate may then be used as the sacrificial layer. If the MEMS element is a capacitive or galvanic switch and is driven by application of an actuation voltage to one or more actuation electrodes, the electrode in the top semiconductor layer is preferably the movable electrode. It is then not necessarily to release the metal layer. Instead, by selectively etching of the shallow trench isolation in advance of the provision of this metal (or polysilicon) layer, additional features can be provided. This is for instance, that the gap between the movable electrode and the fixed—tuning—electrode, is smaller than the gap between the movable electrode and the actuation electrode. Such a design is suitable so as to prevent pull-in of the movable electrode on the fixed electrode. On the other hand, if the MEMS element is to be used as a pressure sensor or as a part of a microfluidic system, the movable electrode may be defined in the metal layer and be designed as a membrane.

With the horizontal version, the fixed electrode is defined in another metal layer. There is in this case no need that the fixed electrode has a similar lateral extension as the movable electrode, and also more than one electrode can be defined therein, such as a tuning electrode and an actuation electrode. Suitably, an etch stop layer is applied on the sacrificial and below this fixed electrode. This etch stop layer is then applied so that the sacrificial layer is effectively and substantially encapsulated by the movable element, the insulating portion of the substrate, one or more of the substrate posts and the etch stop layer. A suitable etch stop layer is a nitride, such as a nitride layer deposited with low-pressure chemical vapour deposition (LPCVD). This nitride layer additionally enhances the maximum capacitance of the MEMS element in its second, closed position.

Alternatively, with this horizontal version, the movable electrode may be part of a movable element that comprises a piezoelectric actuator. Such piezoelectric actuator is suitably a three- or four-layered movable element with a piezoelectric layer between a first and second actuation electrode and optionally a structural layer. This structural layer is present on the side of the substrate, if both actuation electrodes are of the same thickness. Suitably, the structural layer is for instance of silicon nitride, and the first actuation electrode is of platinum, titanium-platinum or the like and the piezoelectric layer is a ferroelectric material such as lead-lanthane-zirkonate-titanate (PLZT).

These and other aspects of the method and the device of the invention will be further explained with reference to the figures that are not drawn to scale and are merely diagrammatical, wherein:

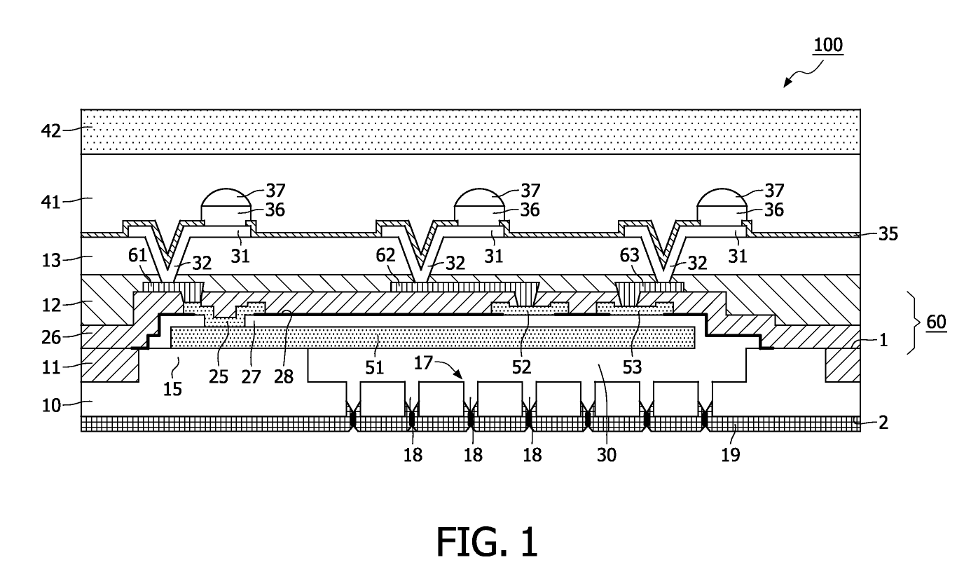

FIG. 1 shows in a cross-sectional view the device of the invention before removal of the temporary carrier.

FIG. 1 shows the device 100 of the invention in a cross-sectional view. As will be clear to the skilled person, a plurality of alternative embodiments is possible in addition to the shown embodiment. Particularly, the MEMS element 60 may be varied, for instance to have electrodes which are oriented substantially perpendicular to a substrate surface 1,2.

The device 100 has a substrate 10, with on its first surface 1 several layers and an encapsulation 40. The substrate 10 comprises posts 15 and a packaging portion 17. Etching holes 18 extend through the packaging portion 17. The substrate 10 is shown here in the situation in which it has already been thinned from the second surface 2. The thinning of the substrate 10 is carried out to a thickness of less than 50 microns, preferably in the range of 20-30 microns, exclusive the thickness of the posts 15. This structure has been made in that the substrate 10 is at its first surface 1 locally oxidized to form a sacrificial layer (not shown), posts 15 and further parts of the oxide layer 11. The sacrificial layer is removed in a further stage of the process to form the cavity 30. The advantage of this specific process is that the cavity is defined from the first side 1 of the substrate 10, in a process similar to the shallow trench oxidation. This process is well controlled so that the dimensions of the cavity may be defined properly.

A conductive pattern, that forms the movable electrode 51 in this embodiment, is applied on top of the sacrificial layer and extends to the at least one post 15. A second sacrificial layer 27 is provided on top of the conductive pattern 51, for instance as a layer of tetra-ethyl-orthosilicate (TEOS). An etch stop layer 28 is provided hereon in a suitably patterned form. In this example, use is made of low pressure chemical vapour deposition (LPCVD) for the deposition of a nitride as etch stop layer 28. Contacts 25 and fixed electrodes 52,53 and optionally other conductive patterns (not shown) are provided hereon. One electrode 52 is an actuation electrode, the other electrode 53 is the sense electrode that defines together with the movable electrode 51 a tunable capacitor, or optionally a switch. More specific designs for the MEMS element 60 suitable for its use as resonator, tunable capacitor, switch, sensor and the like are known to the skilled person in the field of MEMS. The material of these conductive patterns 51, 25, 52, 53 is suitably polysilicon, but could be alternatively a metal such as copper or a copper or aluminium alloy, or even a conductive nitride or oxide, such as TiN or Indium Tin Oxide. It is moreover possible that the conductive pattern 51 is made of another material than the patterns 25, 52, 53. A suitable choice is for instance that the conductive pattern 51, i.e. the movable electrode, is made of polysilicon, while the other patterns are made in TiN with optionally Al. Alternatively, the conductive pattern 51 is provided on a further layer, such as for instance a piezoelectric layer. A piezoelectric MEMS device will then result.

An insulating layer 26 is applied on top of the patterns 25, 52, 53. This is patterned in a conventional manner with photolithography to define interconnects 61, 62, 63. These interconnects 61, 62, 63 are covered with a passivation layer 12. Suitably, but not shown, are further dielectric and metal layers provided for definition of interconnects, contact pads and any passive components such as couplers, striplines, capacitors, resistors and inductors. Moreover, the substrate 10 may include further elements such as transistors or trench capacitors. A circuit for coupling the MEMS element 60 to those further elements is then defined with such interconnects.

A resin layer 13 is provided on the passivation layer 12. In this case use is made of polyimide in a typical thickness of 10 to 20 μm, but alternative thermoplastic materials such as polyacrylates, polysiloxaneimides may be used alternatively. Suitably, the resin layer is compliant and has a resilient nature. Before applying the polyimide, for instance by spincoating, the surface has been cleaned and a primer layer has been provided for improved adhesion. After the application of the polyimide, it is heated first to 125° C. and thereafter to 200° C. Then a photoresist is applied, exposed to a suitable source of radiation and developed. The development includes the structuring of the polyimide layer, so as to create contact windows that expose the interconnects 61,62, 63.

An electrically conducting layer 32 is then provided on the resin layer 13. This conducting layer 32 is provided in a pattern so as to extend through the resin layer 13 in the contact windows therein, and is electrically connected to the underlying interconnects 61, 62, 63. The electrically conductive layer may contain Al or an alloy based on Al. This, in combination with the use of Al for the interconnects 61,62,63 provides a good electrical connection and has the required flexibility to withstand any bending and to release any stress as a result thereof. Alternatively, other materials on the basis of electroplating may be used for the electrically conducting layer 32, and the interconnects 61, 62, 63. The first step in this process is the provision of a base layer by sputtering. This base layer is usually not patterned and very thin. Then, a photoresist is applied and patterned according to the desired pattern of contact pads and conducting tracks. This is followed by electroplating of copper, in a thickness of for instance 0.5-1.3 microns. Finally, the photoresist is removed and the plating base is etched away.

The substrate 10 provided with the MEMS element 60 and the resin layer 13 is then attached to a carrier 42 with removable attaching means 41. This means 41 is in this case a layer of adhesive, which is releasable upon irradiation with UV-radiation. Thereto, the carrier 42 is transparant, and in this example a layer of glass.

Before application to the carrier 42, the electrically conducting layer 32 and the resin layer 13 are covered with a further passivation layer 35. The passivation layer 35 is in this case silicon nitride and is deposited by PECVD at a temperature of about 250° C., in a thickness of approximately 0.5-1.0 micron. Thereafter, the passivation layer 35 is patterned to expose selective areas of the electrically conductive layer 32 that act as contact pads 31. The passivation layer 35 partly extends on the contact pads 31, and functions as a ‘resist defined’ solder mask. The contact pad 31 is thereafter strengthened by deposition of an under bump metallisation 36. In this example, the under bump metallisation 36 comprises nickel and is deposited electroless in a thickness of 2-3 microns. This treatment has the advantage, that no additional mask is needed for the provision of the under bump metallisation 36. Alternatively, copper can be used for the under bump metallisation 36 and be applied by electroplating. In this case, the under bump metallisation 36 and a galvanic bump 37 may be applied in one step. Due to its thickness the under bump metallisation 36 extends over the passivation layer 35.

Finally, a bump 37 is applied on the under bump metallisation 36. In this example, the bump 37 is a solder cap of Sn, SnBi or PbSn, and is applied by immersion into a bath of the desired composition. However, if this under bump metallization 36 is immersed in a bath of pure tin at a temperature of approximately 250° C., then NiSn intermetallics may be formed. And they are formed in the form of needles that protrude through the bump surface. This does not give a useful result. The formation of these intermetallics can be prevented through the use of a low-melting Sn-alloy. Examples of such alloys include SnPb, SnCu and SnBiₓIn_{y}Zn_{z}, wherein at least one of x, y and z is larger than zero. Preferably, a lead-free solder is applied. Advantageously, the alloying elements do not interfere in the reaction between Sn and the metal of the metallisation—particularly Au.

In an advantageous modification, the nickel under bump metallization is provided with a gold adhesion layer before the immersion into the bath. Such a gold adhesion layer is needed for the maintenance of the solderability. However, it has been found that such a gold layer is not needed when the immersion step is carried out directly after the provision of the nickel under bump metallization.

After this attachment of the substrate 10 to the temporary carrier 42, etching holes 18 are provided, and the cavity 30, including its portion 27 on the opposite side of the movable electrode 51 is formed. This removal is effectively carried out with wet-chemical etching. Advantageously, the movable electrode 51 comprises holes or slits so as to provide an effective distribution of the etchant and reduce problems with capillary action. The removal may alternatively be carried out, at least partially with dry etching. Although not shown here, the region of the substrate around the holes 18 could be applied as a further fixed electrode. Evidently, the design of the movable electrode 51 is illustrative only. A doubly or multiply clamped movable electrode 51 could be applied alternatively, and spring structures may be incorporated in this movable electrode 51. Although not shown here, the substrate 10 could be patterned into an island. This may even be carried out simultaneously with the provision of the etching holes 18. The patterning of the substrate into a substrate island has advantageous thermomechanical properties as explained above.

Then a sealing layer 19 is applied so as to cover the etching holes 18. In this example use is made of a PECVD oxide layer. Suitably, the thickness of the sealing layer 19 is of the same order as the width of the holes 18. Then, the cavity 30 will be closed automatically due to the poor step coverage of the PECVD oxide. The resulting pressure in the cavity 30 is equal or similar to the reduced pressure in the reactor used for the deposition of the PECVD oxide. This is for instance 400-800 mTorr.

The temporary carrier 40, as well as the adhesive 41 may thereafter be removed so as to expose the solder bumped contact pads 31. This construction has suitable thermo-mechanical and manufacturing properties.

First of all, the advantage of this construction over a construction in which contact holes are applied in the substrate 10 from the second side 2, is that no additional lithographical steps are needed on the second side 2 of the substrate, except for the definition of the etching holes 18. Evidently, bond pads could be exposed by partial removal of the substrate 10. However, these bond pads will then be recovered during the deposition of the sealing layer 19.

Secondly, the temporary carrier 42 is usually a glass plate. Such a temporary carrier 42 usually has a limited thermal conduction, leading to limited dissipation away from the device 100. Although the present construction only includes rerouted connections from the MEMS element 60 and/or any other elements through the resin layer 13, these may be designed in any size to enable the required heat transfer. Additional connections may be applied specifically for thermal dissipation.

Thirdly, the present invention allows flip-chip assembly of the device 100 to an external board, in which the MEMS element 60 is remote from this external board. This is advantageous for the performance, particularly for sensors and resonators, as the MEMS element 60 will not or not substantially be disturbed by power lines and magnetic fields in or near to such an external board.

Fourthly, the resin layer 13 will acts as a stress release. This appears particularly relevant so as to release stresses during thermal cycling. It is observed that thermal cycling is a relevant problem for such MEMS devices, and particularly in embodiments wherein the MEMS is provided with an actuation electrode and means for providing an actuation voltage, e.g. a resonator, tunable capacitor, switch. The problem is that the needed actuation voltages are rather substantial, which evidently leads to heat dissipation.

1. A method of manufacturing an electronic device that comprises a microelectromechanical (MEMS) element, which is provided with a fixed electrode and a movable electrode that is defined in a cavity and is movable towards and from the fixed electrode between a first gapped position and a second position, said method comprising:
providing a substrate with a first and an opposite second side and with a sacrificial portion, the substrate including the electrodes of the MEMS element;
providing contact pads on the first side of the substrate;
applying a temporary carrier on the contact pads;
providing at least one etching hole in the substrate from the second side to give access to the cavity;
removing the sacrificial portion of the substrate through the at least one etching hole;
closing the at least one etching hole; and
removing the temporary carrier,
wherein
the contact pads are provided on a flexible resin layer that is present on the electrodes of the MEMS element, wherein electrical connections extend through the resin layer to at least one element in the device; and
the substrate is provided with a packaging portion on the second side of the substrate through which the etching holes extend, while the sacrificial portion is at least partially present between the movable electrode and the packaging portion.

2. The method as claimed in claim 1, further comprising patterning the substrate into a first substrate island that includes the MEMS element.

3. The method as claimed in claim 2, wherein patterning of the substrate is carried out simultaneously with formation of the etching holes.

4. The method as claimed in claim 1, further comprising applying bumps on the contact pads prior to providing the temporary carrier.

5. The method as claimed in claim 1, wherein the at least one etching hole is closed by the deposition of a sealing layer.

6. The method as claimed in claim 5, wherein the sealing layer is deposited with chemical vapor deposition.

7. The method as claimed in claim 5, wherein a protecting layer is provided on the second side after applying the sealing layer on the second side of the substrate.

8. The method as claimed in claim 2, wherein separation lanes are defined in an area outside any of the substrate islands.

9. An electronic device comprising a substrate of a semiconductor material with a first and an opposite second side and a microelectromechanical (MEMS) element which is provided with a fixed and a movable electrode, which is defined in a closed cavity and is movable towards and from the fixed electrode between a first gapped position and a second position, the cavity being opened through holes in the substrate that are exposed on the second side of the substrate, said electrodes being coupled to contact pads on the first side, wherein a resin layer is present between the electrodes of the MEMS element and the contact pads, wherein the substrate is provided with a packaging portion on the second side of the substrate through which the etching holes extend, wherein the cavity is at least partially present between the movable electrode and the packaging portion.

10. The electronic device as claimed in claim 9, wherein the substrate is patterned into a first substrate island that comprises the MEMS element.

11. The electronic device as claimed in claim 9, wherein a circuit is present on the first side to interconnect the MEMS elements with further elements within the device, wherein the resin layer covers the circuit and is separated with a passivation layer, and the contact pads are present on the resin layer with vertical interconnects extending through the resin layer to couple the contact pads to the circuit.

12. The electronic device as claimed in claim 11, wherein the passivation layer is present on the resin layer at the first side, the passivation layer leaving the bond pads at least partially exposed.

13. The electronic device as claimed in claim 10, wherein a second substrate island is present in and on which further elements of the circuit are defined, and wherein a conductor between the elements in the first and the second island is geometrically substructured so as to be deformable.
